(19) United States
(12) Patent Application Publication
(10) Pub. No.: US 2024/0235495 A1
(43) Pub. Date: Jul. 11, 2024

(54) POWER AMPLIFIER AND OPERATING METHOD THEREOF

(71) Applicant: Samsung Electro-Mechanics Co., Ltd., Suwon-si (KR)

(72) Inventor: Seungchul PYO, Suwon-si (KR)

(73) Assignee: Samsung Electro-Mechanics Co., Ltd., Suwon-si (KR)

(21) Appl. No.: 18/335,574

(22) Filed: Jun. 15, 2023

(30) Foreign Application Priority Data
Jan. 11, 2023 (KR) 10-2023-0003965

(51) Int. Cl. H03F 1/52; H03F 3/21

(52) U.S. Cl. CPC H03F 1/52; H03F 3/21; H03F 2200/426; H03F 2200/451

(57) ABSTRACT

A power amplifier is provided. The power amplifier may include a power transistor configured to amplify an input Radio Frequency (RF) signal and output the amplified signal, an overvoltage protection circuit configured to detect the magnitude of the input RF signal, and detect the magnitude of an output RF signal of the power transistor, and generate an overvoltage output signal based on the magnitude of the input RF signal and the magnitude of the output RF signal, and a bias circuit configured to generate a bias current to bias the power transistor, and adjust the bias current based on the overvoltage output signal.

### CROSS-REFERENCE TO RELATED APPLICATIONS

This application claims the benefit under 35 USC § 119(a) of Korean Patent Application No. 10-2023-0003965 filed on Jan. 11, 2023, in the Korean Intellectual Property Office, the entire disclosure of which is incorporated herein by reference for all purposes.

### BACKGROUND

### 1. Field

The following description relates to a power amplifier and an operating method thereof.

### 2. Description of Related Art

With the evolution of communications standards, wireless communication systems have adopted various digital modulation and demodulation techniques. The existing Code Division Multiple Access (CDMA) communication systems are adopting the Quadrature Phase Shift Keying (QPSK) technique, and wireless local area networks (LANs), according to IEEE standards for communications, are adopting the Orthogonal Frequency Division Multiplexing (OFDM) technique. Further, Long Term Evolution (LTE) and LTE-Advanced which are the latest standards in 3^{rd} Generation Partnership Project (3GPP) are adopting QPSK, Quadrature Amplitude Modulation (QAM), and the OFDM technique.

Transmitters which are used in wireless communication systems include power amplifiers to amplify Radio Frequency (RF) signals in order to increase their transmission distances.

In the example where the output voltage of a power amplifier exceeds a predetermined threshold level, some problems may occur in the power amplifier. A technique of protecting the power amplifier from this situation is referred to as over voltage protection (OVP). As an example, OVP circuits may protect power amplifiers under the condition that the Voltage Standing Wave Ratio (VSWR) is 10:1 and Pin of Absolute Maximum Ratings (AMR) is 15 dBm. Such OVP circuits may detect only the level of output voltage, so they may malfunction under some conditions (for example, the condition that VSWR is 6:1 and power is max).

The above information disclosed in this Background section is only for enhancement of understanding of the background, and therefore it may contain information that does not form the prior art.

### SUMMARY

This Summary is provided to introduce a selection of concepts in a simplified form that are further described below in the Detailed Description. This Summary is not intended to identify key features or essential features of the claimed subject matter, nor is it intended to be used as an aid in determining the scope of the claimed subject matter.

In a general aspect, a power amplifier, including a power transistor configured to amplify an input Radio Frequency (RF) signal, and output the amplified signal; an overvoltage protection circuit configured to detect a magnitude of the input RF signal, and detect a magnitude of an output RF signal of the power transistor, and generate an overvoltage output signal corresponding to the magnitude of the input RF signal and the magnitude of the output RF signal; and a bias circuit configured to generate bias current to bias the power transistor, and adjust the bias current based on the overvoltage output signal.

The overvoltage protection circuit may be configured to generate the overvoltage output signal indicating an overvoltage state, when the magnitude of the input RF signal is greater than a first reference voltage and the magnitude of the output RF signal is greater than a second reference voltage.

The bias circuit may not generate the bias current or reduce a magnitude of the bias current, when the overvoltage output signal indicates the overvoltage state.

The overvoltage protection circuit may include an input detector configured to detect the magnitude of the input RF signal, an output detector configured to detect the magnitude of the output RF signal, and an overvoltage discriminating unit configured to generate the overvoltage output signal corresponding to an output signal of the input detector and an output signal of the output detector.

The input detector may include an amplifier transistor configured to amplify the input RF signal and output the amplified input RF signal, a diode comprising an anode connected to an output terminal of the amplifier transistor, and a first capacitor that is connected between a cathode of the diode and a ground, and a voltage to which the first capacitor is charged corresponds to the magnitude of the input RF signal.

The output detector may include a plurality of diodes connected between an output terminal of the power transistor and the ground, and a second capacitor connected between a node located between two of the plurality of diodes and the ground, and a voltage to which the second capacitor is charged is the magnitude of the output RF signal.

The overvoltage discriminating unit may include a first comparator configured to compare the output signal of the input detector with a first reference voltage, a second comparator configured to compare the output signal of the output detector with a second reference voltage, and an AND gate configured to receive an output signal of the first comparator and an output signal of the second comparator, and output the overvoltage output signal.

The power transistor may include a first power transistor configured to amplify the input RF signal, and a second power transistor configured to amplify an output RF signal of the first power transistor, and the bias circuit may include a first bias circuit configured to generate a first bias current to bias the first power transistor, and a second bias circuit configured to generate a second bias current to bias the second power transistor, and the magnitude of the output RF signal is a magnitude of an output RF signal of the second power transistor, and at least one of the first bias circuit and the second bias circuit is configured to adjust its own bias current of the first bias current and the second bias current, corresponding to the overvoltage output signal.

In a general aspect, an operating method of a power amplifier that generates an output radio frequency (RF) signal by amplifying an input RF signal includes detecting a magnitude of the input RF signal; detecting a magnitude of the output RF signal; determining an overvoltage state when the magnitude of the input RF signal is greater than a first reference voltage and the magnitude of the output RF signal is greater than a second reference voltage; and adjusting a bias level to bias the power amplifier, in the overvoltage state.

The adjusting of the bias level may include adjusting a bias current to be supplied to a power transistor included in the power amplifier.

The adjusting the bias current may include not generating the bias current or reducing a magnitude of the bias current.

The magnitude of the input RF signal may correspond to an envelope of the input RF signal.

The power amplifier may include a first power transistor configured to amplify the input RF signal, and a second power transistor configured to amplify an output RF signal of the first power transistor, and the magnitude of the output signal may be a magnitude of an output RF signal of the second power transistor.

The detecting the magnitude of the input RF signal may include amplifying the input RF signal, and detecting an envelope of the amplified input RF signal.

In a general aspect, a power amplifier includes a first transistor and a second transistor configured to amplify an input radio frequency (RF) signal; one or more bias circuits configured to generate bias currents, and supply the generated bias currents to the first transistor and the second transistor; an overvoltage protection circuit, including a first comparator configured to receive an input RF signal, compare a magnitude of the input RF signal to a first reference voltage, and output a first signal; a second comparator configured to receive an output RF signal, compare a magnitude of the output RF signal to a second reference voltage, and output a second signal; and an AND gate configured to receive the first signal and the second signal, and output a third signal.

The third signal may be an overvoltage output signal.

The one or more bias circuits may be configured to receive the overvoltage output signal, and adjust a bias current based on the overvoltage output signal.

The output RF signal may be output from at least one of the first transistor and the second transistor.

Other features and aspects will be apparent from the following detailed description, the drawings, and the claims.

### BRIEF DESCRIPTION OF DRAWINGS

FIG. 1 illustrates an example power amplifier, in accordance with one or more embodiments.

FIG. 2 illustrates an example power amplifier, in accordance with one or more embodiments.

FIG. 3 is a block diagram illustrating the internal configuration of an example overvoltage protection circuit, in accordance with one or more embodiments.

FIG. 4 is a circuit diagram illustrating an example input detector of FIG. 3.

FIG. 5 is a circuit diagram illustrating an example output detector of FIG. 3.

FIG. 6 is a circuit diagram illustrating an example overvoltage discriminating unit of FIG. 3.

Throughout the drawings and the detailed description, unless otherwise described or provided, the same drawing reference numerals may be understood to refer to the same or like elements, features, and structures. The drawings may not be to scale, and the relative size, proportions, and depiction of elements in the drawings may be exaggerated for clarity, illustration, and convenience.

### DETAILED DESCRIPTION

The following detailed description is provided to assist the reader in gaining a comprehensive understanding of the methods, apparatuses, and/or systems described herein. However, various changes, modifications, and equivalents of the methods, apparatuses, and/or systems described herein will be apparent after an understanding of the disclosure. For example, the sequences of operations described herein are merely examples, and are not limited to those set forth herein, but may be changed as will be apparent after an understanding of the disclosure, with the exception of operations necessarily occurring in a certain order. Also, descriptions of features that are known after an understanding of the disclosure may be omitted for increased clarity and conciseness.

The features described herein may be embodied in different forms and are not to be construed as being limited to the examples described herein. Rather, the examples described herein have been provided merely to illustrate some of the many possible ways of implementing the methods, apparatuses, and/or systems described herein that will be apparent after an understanding of the disclosure of this application.

The terminology used herein is for describing various examples only and is not to be used to limit the disclosure. The articles “a,” “an,” and “the” are intended to include the plural forms as well, unless the context clearly indicates otherwise. As used herein, the term “and/or” includes any one and any combination of any two or more of the associated listed items. As non-limiting examples, terms “comprise” or “comprises,” “include” or “includes,” and “have” or “has” specify the presence of stated features, numbers, operations, members, elements, and/or combinations thereof, but do not preclude the presence or addition of one or more other features, numbers, operations, members, elements, and/or combinations thereof.

Throughout the specification, when a component or element is described as being “connected to,” “coupled to,” or “joined to” another component or element, it may be directly “connected to,” “coupled to,” or “joined to” the other component or element, or there may reasonably be one or more other components or elements intervening therebetween. When a component or element is described as being “directly connected to,” “directly coupled to,” or “directly joined to” another component or element, there can be no other elements intervening therebetween. Likewise, expressions, for example, “between” and “immediately between” and “adjacent to” and “immediately adjacent to” mayalso be construed as described in the foregoing.

Although terms such as “first,” “second,” and “third”, or A, B, (a), (b), and the like may be used herein to describe various members, components, regions, layers, or sections, these members, components, regions, layers, or sections are not to be limited by these terms. Each of these terminologies is not used to define an essence, order, or sequence of corresponding members, components, regions, layers, or sections, for example, but used merely to distinguish the corresponding members, components, regions, layers, or sections from other members, components, regions, layers, or sections. Thus, a first member, component, region, layer, or section referred to in the examples described herein may also be referred to as a second member, component, region, layer, or section without departing from the teachings of the examples.

Unless otherwise defined, all terms, including technical and scientific terms, used herein have the same meaning as commonly understood by one of ordinary skill in the art to which this disclosure pertains and based on an understanding of the disclosure of the present application. Terms, such as those defined in commonly used dictionaries, are to be interpreted as having a meaning that is consistent with their meaning in the context of the relevant art and the disclosure of the present application and are not to be interpreted in an idealized or overly formal sense unless expressly so defined herein. The use of the term “may” herein with respect to an example or embodiment, e.g., as to what an example or embodiment may include or implement, means that at least one example or embodiment exists where such a feature is included or implemented, while all examples are not limited thereto.

Throughout this specification, RF signals may have formats according to Wi-Fi (such as IEEE 802.11 family), WiMAX (such as IEEE 802.16 family), IEEE 802.20, Long Term Evolution (LTE), Evolution-Data Optimized (Ev-DO), high-speed packet access plus (HSPA+), high-speed downlink packet access plus (HSDPA+), high-speed uplink packet access plus (HSUPA+), Enhanced Data GSM Evolution (EDGE), Global System for Mobile communication (GSM), Global Positioning System (GPS), General Packet Radio Service (GPRS), Code Division Multiple Access (CDMA), Time Division Multiple Access (TDMA), digital enhanced cordless communication (DECT), Bluetooth, third generation (3G), fourth generation (4G), fifth generation (5G), and arbitrary other wireless and wired communication protocols designated as the next ones, but is not limited thereto.

One or more examples may provide a power amplifier and an operating method thereof having advantages of being able to prevent erroneous OVP operations.

One or more examples may prevent erroneous OVP operations by performing OVP operations depending on the magnitudes of input RF signals as well as the magnitudes of output RF signals.

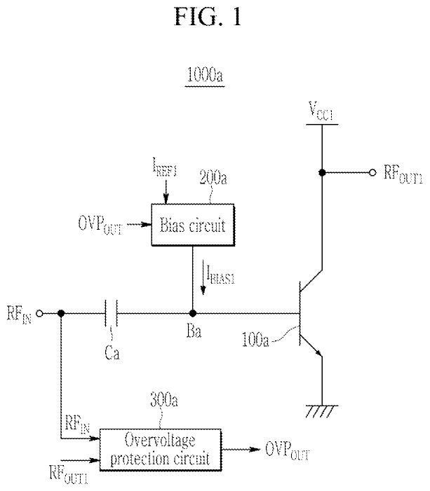

FIG. 1 illustrates an example power amplifier 1000a, in accordance with one or more embodiments.

As illustrated in FIG. 1, the example power amplifier 1000a, in accordance with one or more embodiments, may include a power transistor 100a, a bias circuit 200a, an overvoltage protection circuit 300a, and a coupling capacitor Ca.

The power transistor 100a may amplify the power of an RF signal input to its input terminal Ba, and output the amplified signal through its output terminal (i.e., its collector). In other words, the base of the power transistor 100a may receive an RF signal to be amplified, and the collector of the power transistor 100a may output the amplified RF signal. In FIG. 1, an input RF signal which is input to the power transistor 100a is denoted by ‘RF_{IN}’, and an output RF signal which is output from the power transistor 100a is denoted by ‘RF_{OUT1}’. The emitter of the power transistor 100a may be connected to a ground, and although not shown in FIG. 1, in an example, a resistor may be additionally connected between the emitter of the power transistor 100a and the ground. Further, the collector of the power transistor 100a may be connected to a power voltage V_{CC1}, and the power transistor 100a may be operated by the power voltage V_{CC1}. Alternatively, the collector of the power transistor 100a may be connected to the power voltage V_{CC1} through an inductor (not shown in FIG. 1) configured to perform an RF choke operation.

The power transistor 100a may be configured with various transistors such as, but not limited to, heterojunction bipolar transistors (HBTs), bipolar junction transistors (BJTs), and insulated gate bipolar transistors (IGBTs). Further, although the power transistor 100a is shown in FIG. 1 as being of the n type, this is only an example, and it may be replaced with a p type transistor.

In an example, a coupling capacitor Ca may be connected to the input terminal (i.e., base) of the power transistor 100a. The coupling capacitor Ca may perform an operation of blocking Direct Current (DC) components of input RF signals RF_{IN}.

In the example where an output RF signal RF_{OUT1} becomes excessively large in an abnormal state, the power transistor 100a may be destroyed or may malfunction. Further, in an abnormal state, the input RF signal RF_{IN} may become excessively large. Then, some problems may occur in the power transistor 100a. Accordingly, the overvoltage protection circuit 300a, in accordance with one or more embodiments, may detect the input RF signal RF_{IN} as well as the output RF signal RF_{OUT1}, and generate an overvoltage output signal OVP_{OUT} based on the two detected signals.

The bias circuit 200a may receive reference current I_{REF1} from an external source and generate bias current I_{BIA1} using the reference current I_{REF1}. The bias current I_{BIAS1} may be supplied to the input terminal Ba of the power transistor 100a, and the bias level (bias point) of the power transistor 100a may be set by the bias current I_{BIAS1}. A detailed description of how the bias circuit 200a generates the bias current I_{BIAS1} using the reference current I_{REF1} will not be made since it is apparent to those skilled in the art.

In an example, the bias circuit 200a, in accordance with one or more embodiments, may receive the overvoltage output signal OVP_{OUT} from the overvoltage protection circuit 300a, and the bias circuit 200a may adjust the bias current I_{BIAS1} based on the received overvoltage output signal OVP_{OUT}. In other words, the bias circuit 200a may adjust the bias level of the power transistor 100a, based on the overvoltage output signal OVP_{OUT}. In an example, the bias circuit 200a may not generate bias current I_{BIAS1} when the overvoltage output signal OVP_{OUT} is at a high level. In this example, since the power transistor 100a does not operate, it can be protected. As another example, when the overvoltage output signal OVP_{OUT} is at the high level, the bias circuit 200a may reduce the magnitude of the bias current I_{BIAS1}. In this example, since the power transistor 100a is biased low, it can be protected from overvoltage.

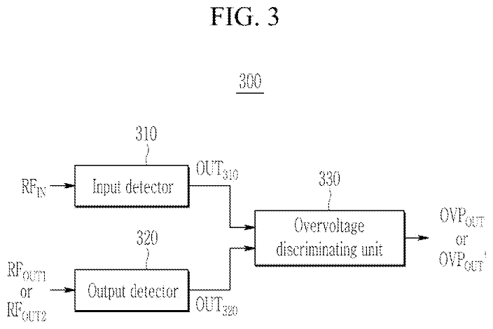

The overvoltage protection circuit 300a may receive the input RF signal RF_{IN} and the output RF signal RF_{OUT1}, and detect the respective magnitudes of the input RF signal RF_{IN} and the output RF signal RF_{OUT1}. The overvoltage protection circuit 300a may compare the detected magnitude of the input RF signal RF_{IN} and a predetermined reference voltage V_{REF1}, and compare the detected magnitude of the output RF signal RF_{OUT1} and a predetermined reference voltage V_{REF2}. The overvoltage protection circuit 300a may generate an overvoltage output signal OVP_{OUT} based on the comparison results. The specific configuration and operation of such an overvoltage protection circuit will be described below in detail with reference to FIG. 3 to FIG. 6.

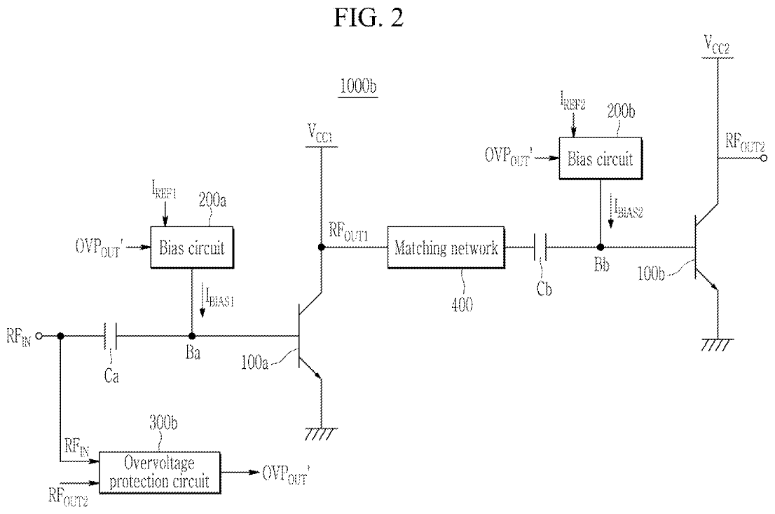

FIG. 2 illustrates an example power amplifier 1000b, in accordance with one or more embodiments.

As illustrated in FIG. 2, the example power amplifier 1000b, in accordance with one or more embodiments, may include the power transistor 100a, the bias circuit 200a, a power transistor 100b, a bias circuit 200b, a matching network 400, and an overvoltage protection circuit 300b. The power amplifier 1000b of FIG. 2 maybe similar to the power amplifier 1000a of FIG. 1, except that it has a multi-stage amplifier structure which can be obtained by expanding the power amplifier 1000a of FIG. 1.

In an example, the matching network 400 may be connected between the output terminal (i.e., collector) of the power transistor 100a and the input terminal Bb (i.e., base) of the power transistor 100b. The matching network 400 performs impedance matching between the output RF signal RF_{OUT1} and the power transistor 100b. In an example, the matching network 400 may be configured with at least one combination of resistors, inductors, and capacitors, but is not limited thereto.

The power transistor 100b may amplify the power of an RF signal input to its input terminal Bb, and output it through its output terminal (i.e., its collector). In other words, the base of the power transistor 100b may receive an RF signal (i.e., the output RF signal RF_{OUT1}) to be amplified, and the collector of the power transistor 100b may output the amplified RF signal. In FIG. 2, an output RF signal which is output from the power transistor 100b is denoted by ‘RF_{OUT2}’. The emitter of the power transistor 100b may be connected to a ground, and although not shown in FIG. 2, in an example, a resistor may be additionally connected between the emitter of the power transistor 100b and the ground. Further, the collector of the power transistor 100b may be connected to a power voltage V_{CC2}, and the power transistor 100b may be operated or controlled by the power voltage V_{CC2}. Alternatively, in an example, the collector of the power transistor 100b may be connected to the power voltage V_{CC2} through an inductor (not shown in FIG. 2) configured to perform an RF choke operation.

In a non-limited example, the power transistor 100b may be configured with various transistors such as, but not limited to, heterojunction bipolar transistors (HBTs), bipolar junction transistors (BJTs), and insulated gate bipolar transistors (IGBTs). Further, although the power transistor 100b is illustrated in FIG. 2 as being of the n type, this is only an example, and the power transistor 100b may be replaced with a p type transistor.

A coupling capacitor Cb may be connected between the matching network 400 and the input terminal (i.e., base) of the power transistor 100b. The coupling capacitor Cb may perform an operation of blocking Direct Current (DC) components of input RF signals (i.e., RF_{OUT1}).

The overvoltage protection circuit 300b of FIG. 2 mayreceive an output RF signal RF_{OUT2}, unlike the overvoltage protection circuit 300a of FIG. 1. In other words, since the final output RF signal is the output RF signal RF_{OUT2} which is output from the power transistor 100b, the overvoltage protection circuit 300b may receive the output RF signal RF_{OUT2} instead of the output RF signal RF_{OUT1}. The overvoltage protection circuit 300b may detect the input RF signal RF_{IN} and the output RF signal RF_{OUT2}, and generate an overvoltage output signal OVP_{OUT}′ that is based on the two detected signals.

The bias circuit 200a of FIG. 2 may receive the overvoltage output signal OVP_{OUT}′ from the overvoltage protection circuit 300b, and the bias circuit 200a may adjust the bias current I_{BIAS1}, based on the received overvoltage output signal OVP′. In other words, the bias circuit 200a may adjust the bias level of the power transistor 100a, based on the received overvoltage output signal OVP_{OUT}′. In an example, the bias circuit 200a may not generate bias current I_{BIAS1} when the overvoltage output signal OVP_{OUT}′ is at a high level. In this example, since the power transistor 100a would not operate, it can be protected. In another example, when the overvoltage output signal OVP_{OUT}′ is at the high level, the bias circuit 200a may reduce the magnitude of the bias current I_{BIAS1}. In this example, since the power transistor 100a is biased low, it can be protected from overvoltage.

The bias circuit 200b may receive reference current I_{REF2} from an external source, and generate bias current I_{BIAS2} using the reference current I_{REF2}. The bias current I_{BIAS2} may be supplied to the input terminal Bb of the power transistor 100b, and the bias level (bias point) of the power transistor 100b may be set by the bias current I_{BIAS2}. A detailed description of how the bias circuit 200b generates the bias current I_{BIAS2} using the reference current I_{REF2} will not be made since it is apparent to those skilled in the art.

In an example, the bias circuit 200b may receive the overvoltage output signal OVP_{OUT}′ from the overvoltage protection circuit 300b, and the bias circuit 200b may adjust the bias current I_{BIAS2}, based on the received overvoltage output signal OVP_{OUT}′. In other words, the bias circuit 200b may adjust the bias level of the power transistor 100b, depending on the received overvoltage output signal OVP_{OUT}′. In an example, the bias circuit 200b may not generate any bias current I_{BIAS2} when the overvoltage output signal OVP_{OUT}′ is at a high level. In this example, since the power transistor 100b may not operate, it can be protected. In another example, when the overvoltage output signal OVP_{OUT}′ is at the high level, the bias circuit 200b may reduce the magnitude of the bias current I_{BIAS2}. In this example, since the power transistor 100b is biased low, it can be protected from overvoltage.

The overvoltage protection circuit 300b may receive the input RF signal RF_{IN} and the output RF signal RF_{OUT2}, and detect the magnitudes of the input RF signal RF_{IN} and the output RF signal RF_{OUT2}. The overvoltage protection circuit 300b may compare the detected magnitude of the input RF signal RF_{IN} and a predetermined reference voltage V_{REF1}, and compare the detected magnitude of the output RF signal RF_{OUT2} and a predetermined reference voltage V_{REF2}. The overvoltage protection circuit 300b may generate an overvoltage output signal OVP_{OUT}′, based on the comparison results. The specific configuration and operation of such an overvoltage protection circuit will be described below in detail with reference to FIG. 3 to FIG. 6.

Further, in FIG. 2, at least one of the bias circuit 200a and the bias circuit 200b may receive the overvoltage output signal OVP_{OUT}′ from the overvoltage protection circuit 300b. In an example, at least one of the bias circuit 200a and the bias circuit 200b may adjust the bias current, based on the received overvoltage output signal OVP_{OUT}′. In an example, the bias circuit 200a may not receive the overvoltage output signal OVP_{OUT}′, and the bias circuit 200b may receive the overvoltage output signal OVP_{OUT}′. In another example, the bias circuit 200a may receive the overvoltage output signal OVP_{OUT}′, and the bias circuit 200b may not receive the overvoltage output signal OVP_{OUT}′. As yet another example, both of the bias circuit 200aand the bias circuit 200b may receive the overvoltage output signal OVP_{OUT}′.

The overvoltage protection circuit 300a of FIG. 1 and the overvoltage protection circuit 300b of FIG. 2 are similar to each other in their specific configurations and operations except that the overvoltage protection circuit 300a receives the output RF signal RF_{OUT1} and the overvoltage protection circuit 300b receives the output RF signal RF_{OUT2}, and will be described below in detail with reference to FIG. 3.

FIG. 3 is a block diagram illustrating the internal configuration of an example overvoltage protection circuit 300, in accordance with one or more embodiments.

In an example, the overvoltage protection circuit 300 of FIG. 3 maybe the overvoltage protection circuit 300a of FIG. 1 or the overvoltage protection circuit 300b of FIG. 2.

As illustrated in FIG. 3, the example overvoltage protection circuit 300, in accordance with one or more embodiments, may include an input detector 310, an output detector 320, and an overvoltage discriminating unit 330.

The input detector 310 may receive the input RF signal RF_{IN} and detect the magnitude of the received input RF signal RF_{IN}. In FIG. 3, the magnitude of the input RF signal RF_{IN} detected by the input detector 310 is denoted by the ′input RF signal magnitude OUT₃₁₀′. The input detector 310 may output the input RF signal magnitude OUT₃₁₀ to the overvoltage discriminating unit 330.

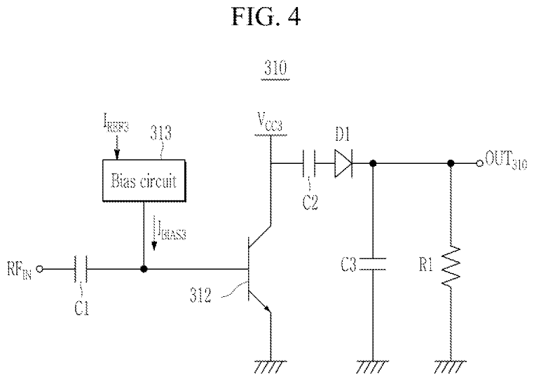

FIG. 4 is a circuit diagram illustrating an example of the input detector 310 of FIG. 3.

As illustrated in FIG. 4, the input detector 310 may include an amplifier transistor 312, a bias circuit 313, a capacitor C1, a capacitor C2, a diode D1, a capacitor C3, and a resistor R1.

The input RF signal RF_{IN} may be input to the input terminal (i.e., base) of the amplifier transistor 312 through the capacitor C1. Here, the capacitor C1 may be a coupling capacitor to perform an operation of blocking Direct Current (DC) components of the input RF signal RF_{IN}.

The amplifier transistor 312 may amplify the input RF signal RF_{IN} input to the input terminal (i.e., the base), and output it through the output terminal (i.e., the collector). Since the input RF signal RF_{IN} may be too small a signal to detect, the input RF signal RF_{IN} may be amplified by the amplifier transistor 312. The emitter of the amplifier transistor 312 may be connected to the ground, and although not shown in FIG. 4, in an example, a resistor may be additionally connected between the emitter of the amplifier transistor 312 and the ground. Further, the collector of the amplifier transistor 312 may be connected to a power voltage V_{CC3}, and the amplifier transistor 312 may be operated by the power voltage V_{CC3}. Alternatively, the collector of the amplifier transistor 312 may be connected to the power voltage V_{CC3} through an inductor (not shown in FIG. 4) configured to perform an RF choke function.

The amplifier transistor 312 may be configured with various transistors such as heterojunction bipolar transistors (HBTs), bipolar junction transistors (BJTs), and insulated gate bipolar transistors (IGBTs). Further, although the amplifier transistor 312 is illustrated in FIG. 4 as being of the n type, that is only an example, and it may be replaced with a p type transistor.

The bias circuit 313 may generate bias current I_{BIAS3} using reference current I_{REF3}. The bias current I_{BIAS3} may be supplied to the input terminal (i.e., base) of the amplifier transistor 312, and the bias level (bias point) of the amplifier transistor 312 may be set by the bias current I_{BIAS3}. A detailed description of how the bias circuit 313 generates the bias current I_{BIAS3} using the reference current I_{REF3} will not be made since it is apparent to those skilled in the art.

The capacitor C2 may be connected between the output terminal (i.e., collector) of the amplifier transistor 312 and the anode of the diode D1. In an example, the capacitor C2 may be a coupling capacitor that performs an operation of blocking Direct Current (DC) components of the RF signal output from the amplifier transistor 312.

The cathode of the diode D1 may be connected to a first end of the capacitor C3 and a first end of the resistor R1. The second end of the capacitor C3 may be connected to the ground, and the second end of the resistor R1 may be connected to the ground. In an example, through the diode D1 and the capacitor C3, the magnitude level of the RF signal output from the amplifier transistor 312 may be detected. In an example, the diode D1 and the capacitor C3 may perform an operation of detecting the envelop of the RF signal output from the amplifier transistor 312. In other words, from the contact point of the diode D1 and the capacitor C3, the input RF signal magnitude OUT₃₁₀ may be output. In an example, the resistor R1 may stabilize voltage to which the capacitor C3 is charged.

In FIG. 4, the input RF signal RF_{IN} may be amplified by the amplifier transistor 312, and the signal output from the amplifier transistor 312 may be converted into an envelope signal by the diode D1 and the capacitor C3. This envelope signal may be the input RF signal magnitude OUT₃₁₀.

The output detector 320 of FIG. 3 mayreceive the output RF signal RF_{OUT1} described with reference to FIG. 1 or the output RF signal RF_{OUT2} described with reference to FIG. 2, and detect the magnitude of the output RF signal RF_{OUT1} or the magnitude of the output RF signal RF_{OUT2}. In the example where the overvoltage protection circuit 300 of FIG. 3 is the overvoltage protection circuit 300a of FIG. 1, the output detector 320 may detect the output RF signal RF_{OUT1}. In the example where the overvoltage protection circuit 300 of FIG. 3 is the overvoltage protection circuit 300b of FIG. 2, the output detector 320 may detect the output RF signal RF_{OUT2}. In FIG. 3, the magnitude of the output RF signal RF_{OUT1} or RF_{OUT2} detected by the output detector 320 is denoted by the ′output RF signal magnitude OUT₃₂₀′. The output detector 320 may output the output RF signal magnitude OUT₃₁₀ to the overvoltage discriminating unit 330.

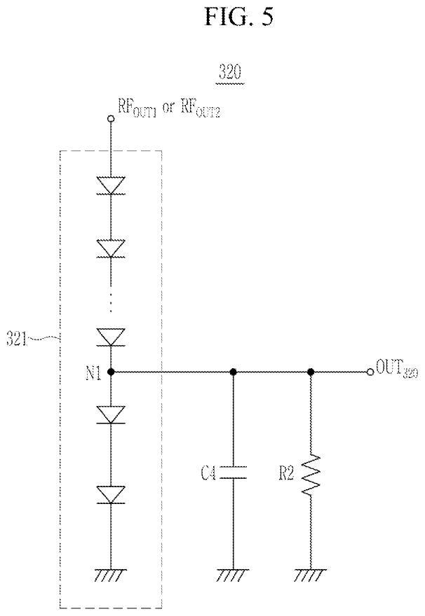

FIG. 5 is a circuit diagram illustrating an example of the output detector 320 of FIG. 3, in accordance with one or more embodiments.

As illustrated in FIG. 5, the output detector 320 may include a plurality of diodes 321, a capacitor C4, and a resistor R2.

The plurality of diodes 321 may be stacked and may be connected. The number of diodes included in the plurality of diodes 321 may be changed depending on the intended implementation of the output RF signal RF_{OUT1} or RF_{OUT2}.

In an example, the plurality of stacked diodes 321 may be connected between the output terminal (i.e., collector) of the power transistor 100a and the ground. In other words, the output RF signal RF_{OUT1} may be input to the plurality of diodes 321, and the plurality of diodes 321 may be turned on based on the magnitude of the output RF signal RF_{OUT1}.

In another example, the plurality of stacked diodes 321 may be connected between the output terminal (i.e., collector) of the power transistor 100b and the ground. In other words, the output RF signal RF_{OUT2} may be input to the plurality of diodes 321, and the plurality of diodes 321 may be turned on based on the magnitude of the output RF signal RF_{OUT2}.

A first end of the capacitor C4 may be connected to a node N1 located between two of the plurality of diodes 321. In an example, the location of the node N1 may be changed depending on an implementation of the output RF signal RF_{OUT1} or RF_{OUT2}. A second end of the capacitor C4 may be connected to the ground. The resistor R2 may be connected between the node N1 and the ground. The resistor R2 may stabilize voltage to which the capacitor C4 is charged.

In the example where the output RF signal RF_{OUT1} or RF_{OUT2} exceeds a threshold level, the plurality of diodes 321 may be turned on. The voltage on the node N1 may be detected by turning on the plurality of diodes 321. The capacitor C4 may be charged to the voltage detected from the node N1, and the voltage to which the capacitor C4 is charged may be the output RF signal magnitude OUT₃₂₀.

The overvoltage discriminating unit 330 of FIG. 3 mayreceive the input RF signal magnitude OUT₃₁₀ from the input detector 310, and receive the output RF signal magnitude OUT₃₂₀ from the output detector 320. The overvoltage discriminating unit 330 may compare the input RF signal magnitude OUT₃₁₀ and the reference voltage V_{REF1}, and compare the output RF signal magnitude OUT₃₂₀ and the reference voltage V_{REF2}. The overvoltage protection circuit 300a may generate the overvoltage output signal OVP_{OUT} or OVP_{OUT}' depending on the comparison results. In an example, the overvoltage discriminating unit 330 may generate and output the overvoltage output signal OVP_{OUT} based on the output RF signal RF_{OUT1}. Further, the overvoltage discriminating unit 330 may generate and output the overvoltage output signal OVP_{OUT}′, based on the output RF signal RF_{OUT2}.

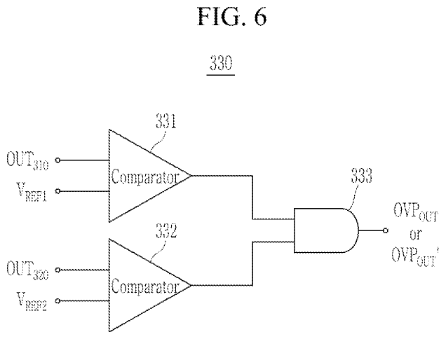

FIG. 6 is a circuit diagram illustrating an example of the overvoltage discriminating unit 330 of FIG. 3, in accordance with one or more embodiments.

As illustrated in FIG. 6, the overvoltage discriminating unit 330 may include a first comparator 331, a second comparator 332, and an AND gate 333.

The first comparator 331 may receive the input RF signal magnitude OUT₃₁₀ and the reference voltage V_{REF1}. The first comparator 331 may output a high-level signal when the input RF signal magnitude OUT₃₁₀ is higher than the reference voltage V_{REF1}. Further, the first comparator 331 may output a low-level signal when the input RF signal magnitude OUT₃₁₀ is lower than the reference voltage V_{REF1}. In an example, the reference voltage V_{REF1} may be applied from the outside, and may have a level that is based on an desired implementation.

The second comparator 332 may receive the output RF signal magnitude OUT and the reference voltage V_{REF2}. The second comparator 332 may output a high-level signal when the output RF signal magnitude OUT is higher than the reference voltage V_{REF2}. Further, the second comparator 332 may output a low-level signal when the output RF signal magnitude OUT₃₂₀ is lower than the reference voltage V_{REF2}.

The AND gate 333 may receive the output signal of the first comparator 331 and the output signal of the second comparator 332, and perform a logic AND operation. In other words, the AND gate 333 may output a high signal when the output signal of the first comparator 331 is at the high level and the output signal of the second comparator 332 is at the high level. Further, the AND gate 333 may output a low signal when at least one of the output signal of the first comparator 331 and the output signal of the second comparator 332 is at the low level. The output signal of the AND gate 333 may be the overvoltage output signal OVP_{OUT} or OVP_{OUT}′.

Therefore, when the input RF signal magnitude OUT₃₁₀ is higher than the reference voltage V_{REF1}, and the output RF signal magnitude OUT₃₂₀ is higher than the reference voltage V_{REF2}, the overvoltage output signal OVP_{OUT} or OVP_{OUT}′ maybe at the high level. Otherwise, the overvoltage output signal OVP_{OUT} or OVP_{OUT}′ maybe at the low level.

In FIG. 1, when the overvoltage output signal OVP_{OUT} is at the high level, the bias circuit 200a may adjust the bias current I_{BIAS1}. In an example, when the overvoltage output signal OVP_{OUT} is at the high level, the bias circuit 200a may not generate any bias current I_{BIAS1}. In other words, the bias circuit 200a may be turned off, whereby the power transistor 100a may be turned off. A detailed description of how the bias circuit 200a adjusts the bias current I_{BIAS1} will not be made since it is apparent to those skilled in the art.

In FIG. 2, when the overvoltage output signal OVP_{OUT}′ is at the high level, at least one of the bias circuit 200a and the bias circuit 200b may adjust its own bias current. As an example, when the overvoltage output signal OVP_{OUT}′ is at the high level, at least one of the bias circuit 200a and the bias circuit 200b may not generate its own bias current. In other words, at least one of the bias circuit 200a and the bias circuit 200b may be turned off, whereby at least one of the power transistor 100a and the power transistor 100b may be turned off. A detailed description of how at least one of the bias circuit 200a and the bias circuit 200b adjusts its own bias current will not be made since it is apparent to those skilled in the art.

Accordingly, at least one embodiment of the above-described embodiments may perform a protection operation using the magnitude of the input RF signal as well as the magnitude of the output RF signal, thereby being able to more stably perform the RF OVP operation.

While this disclosure includes specific examples, it will be apparent to one of ordinary skill in the art, after an understanding of the disclosure of this application, that various changes in form and details may be made in these examples without departing from the spirit and scope of the claims and their equivalents. The examples described herein are to be considered in a descriptive sense only, and not for purposes of limitation. Descriptions of features or aspects in each example are to be considered as being applicable to similar features or aspects in other examples. Suitable results may be achieved if the described techniques are performed in a different order, and/or if components in a described system, architecture, device, or circuit are combined in a different manner, and/or replaced or supplemented by other components or their equivalents.

Therefore, in addition to the above disclosure, the scope of the disclosure may also be defined by the claims and their equivalents, and all variations within the scope of the claims and their equivalents are to be construed as being included in the disclosure.

What is claimed is:

1. A power amplifier, comprising:
a power transistor configured to amplify an input Radio Frequency (RF) signal, and output the amplified signal;
an overvoltage protection circuit configured to detect a magnitude of the input RF signal, and detect a magnitude of an output RF signal of the power transistor, and generate an overvoltage output signal corresponding to the magnitude of the input RF signal and the magnitude of the output RF signal; and
a bias circuit configured to generate bias current to bias the power transistor, and adjust the bias current based on the overvoltage output signal.

2. The power amplifier of claim 1, wherein:
the overvoltage protection circuit is configured to generate the overvoltage output signal indicating an overvoltage state, when the magnitude of the input RF signal is greater than a first reference voltage and the magnitude of the output RF signal is greater than a second reference voltage.

3. The power amplifier of claim 2, wherein:
the bias circuit does not generate the bias current or reduce a magnitude of the bias current, when the overvoltage output signal indicates the overvoltage state.

4. The power amplifier of claim 1, wherein:
the overvoltage protection circuit comprises:
an input detector configured to detect the magnitude of the input RF signal,
an output detector configured to detect the magnitude of the output RF signal, and
an overvoltage discriminating unit configured to generate the overvoltage output signal corresponding to an output signal of the input detector and an output signal of the output detector.

5. The power amplifier of claim 4, wherein:
the input detector comprises:
an amplifier transistor configured to amplify the input RF signal and output the amplified input RF signal,
a diode comprising an anode connected to an output terminal of the amplifier transistor, and
a first capacitor that is connected between a cathode of the diode and a ground, and
a voltage to which the first capacitor is charged corresponds to the magnitude of the input RF signal.

6. The power amplifier of claim 5, wherein:
the output detector comprises:
a plurality of diodes connected between an output terminal of the power transistor and the ground, and
a second capacitor connected between a node located between two of the plurality of diodes and the ground, and
a voltage to which the second capacitor is charged is the magnitude of the output RF signal.

7. The power amplifier of claim 4, wherein:
the overvoltage discriminating unit comprises:
a first comparator configured to compare the output signal of the input detector with a first reference voltage,
a second comparator configured to compare the output signal of the output detector with a second reference voltage, and
an AND gate configured to receive an output signal of the first comparator and an output signal of the second comparator, and output the overvoltage output signal.

8. The power amplifier of claim 1, wherein:
the power transistor comprises a first power transistor configured to amplify the input RF signal, and a second power transistor configured to amplify an output RF signal of the first power transistor,
the bias circuit comprises a first bias circuit configured to generate a first bias current to bias the first power transistor, and a second bias circuit configured to generate a second bias current to bias the second power transistor,
the magnitude of the output RF signal is a magnitude of an output RF signal of the second power transistor, and
at least one of the first bias circuit and the second bias circuit is configured to adjust its own bias current of the first bias current and the second bias current, corresponding to the overvoltage output signal.

9. An operating method of a power amplifier that generates an output radio frequency (RF) signal by amplifying an input RF signal, comprising:
detecting a magnitude of the input RF signal;
detecting a magnitude of the output RF signal;
determining an overvoltage state when the magnitude of the input RF signal is greater than a first reference voltage and the magnitude of the output RF signal is greater than a second reference voltage; and
adjusting a bias level to bias the power amplifier, in the overvoltage state.

10. The method of claim 9, wherein:
the adjusting of the bias level comprises adjusting a bias current to be supplied to a power transistor included in the power amplifier.

11. The method of claim 10, wherein:
the adjusting the bias current comprises not generating the bias current or reducing a magnitude of the bias current.

12. The method of claim 9, wherein:
the magnitude of the input RF signal corresponds to an envelope of the input RF signal.

13. The method of claim 9, wherein:
the power amplifier comprises a first power transistor configured to amplify the input RF signal, and a second power transistor configured to amplify an output RF signal of the first power transistor, and
the magnitude of the output signal is a magnitude of an output RF signal of the second power transistor.

14. The method of claim 9, wherein:
the detecting the magnitude of the input RF signal comprises:
amplifying the input RF signal, and detecting an envelope of the amplified input RF signal.

15. A power amplifier, comprising:
a first transistor and a second transistor configured to amplify an input radio frequency (RF) signal;
one or more bias circuits configured to generate bias currents, and supply the generated bias currents to the first transistor and the second transistor;
an overvoltage protection circuit, comprising
a first comparator configured to receive an input RF signal, compare a magnitude of the input RF signal to a first reference voltage, and output a first signal;
a second comparator configured to receive an output RF signal, compare a magnitude of the output RF signal to a second reference voltage, and output a second signal; and
an AND gate configured to receive the first signal and the second signal, and output a third signal.

16. The power amplifier of claim 15, wherein the third signal is an overvoltage output signal.

17. The power amplifier of claim 16, wherein the one or more bias circuits are configured to receive the overvoltage output signal, and adjust a bias current based on the overvoltage output signal.

18. The power amplifier of claim 15, wherein the output RF signal is output from at least one of the first transistor and the second transistor.
